(19) United States
(12) Patent Application Publication
(10) Pub. No.: US 2007/0252133 A1
(43) Pub. Date: Nov. 1, 2007

(54) Light emitting apparatus

(75) Inventor: Sean Chang, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS INC.

(21) Appl. No.: 11/783,721

(22) Filed: Apr. 11, 2007

(30) Foreign Application Priority Data
Apr. 28, 2006 (TW) 095115255

(51) Int. Cl. H01L 29/06

(52) U.S. Cl. 257/13

(57) ABSTRACT

A light emitting apparatus includes a substrate, a first metal layer, at least one light emitting device and a protective layer for covering the light emitting device. The first metal layer is disposed on the substrate and includes a structure for increasing the light emitting efficiency. The light emitting device is disposed at a predetermined position of the first metal layer and on the substrate. The light emitting device emits a light and the light is then reflected and concentrated to project out by the structure of the first metal layer. Thus, the light emitting efficiency is improved.

### DETAILED DESCRIPTION OF THE INVENTION

### Cross Reference To Related Applications

This Non-provisional application claims priority under 35 U.S.C. §119(a) on Patent Application No(s). 095115255 filed in Taiwan, Republic of China on Apr. 28, 2006, the entire contents of which are hereby incorporated by reference.

### BACKGROUND OF THE INVENTION

1. Field of Invention

The invention relates to a light emitting apparatus and in particular to a light emitting apparatus having good heat dissipating efficiency.

2. Related Art

With the development of the opto-electronic industry, light emitting devices, such as LEDs (Light Emitting Diodes), have been widely and variously applied to display functions of electronic products.

Referring to FIG. 1, a conventional LED light emitting apparatus 1 includes a substrate 10, an insulating layer 11, a plurality of LED light emitting devices 12, a metal layer 13 and a package layer 14. The insulating layer 11 is disposed on the substrate 10. The light emitting devices 12 are disposed on the insulating layer 11. The metal layer 13 is disposed on the insulating layer 11 and is electrically connected to the light emitting devices 12 by way of wire bonding. The package layer 14 covers the LED light emitting devices 12 so as to protect the light emitting devices 12 from being influenced and damaged by mechanical factors, heat, moisture or other factors.

When the conventional LED light emitting apparatus 1 emits lights, parts of the lights leaks from the lateral side of the light emitting device 12 and the outputted lights can not be completely converged onto the light emitting surface, so that the light emitting efficiency cannot be effectively enhanced. Meanwhile, with the development of ever higher efficiency and ever higher luminance of the light emitting apparatus 1, the light emitting device 12 also generates heat during its operation, and the accumulated heat raises the temperature, influencing the light emitting efficiency and shortening the lifetime of the light emitting device 12. Further, because the conventional light emitting device 12 is disposed on the insulating layer 11 with a poor heat dissipating property, and the airtight seal of the package layer 14 prevents the heat generated by the light emitting device 12 from being dissipated easily, the heat dissipating problem becomes increasingly significant.

It is therefore a subject of the invention to provide a light emitting apparatus, which can be manufactured simply and has high light emitting efficiency, high heat dissipating effect and reduced cost.

### SUMMARY OF THE INVENTION

In view of the foregoing, the invention is to provide a light emitting apparatus, which can be manufactured simply and has high light emitting efficiency, high heat dissipating effect and reduced cost.

To achieve the above, the invention discloses a light emitting apparatus including a substrate, a first metal layer, at least one light emitting device and a protective layer. The first metal layer is disposed on the substrate and has a structure for increasing the light emitting efficiency. The light emitting device is disposed at a predetermined position of the first metal layer and on the substrate, and the protective layer covers the light emitting device.

As mentioned hereinabove, the light emitting device is disposed at the predetermined position of the first metal layer in the light emitting apparatus according to the present invention. Regarding to the material characteristics of the first metal layer, an insulating layer can be directly formed after performing a ceramization procedure, and the light emitting device can be disposed on the insulating layer. Also, the light emitting efficiency is enhanced because the structure on the first metal layer can reflect and concentrate the light outputted from the light emitting device. Meanwhile, superior heat dissipating effect and thus longer lifetime of the light emitting apparatus may be achieved by using the substrate which has advantages of good thermal conductivity, large area, and may be composed of metal or alloys to guide and dissipate the heat generated by the light emitting device during operation. Compared with the prior art, it is unnecessary to dispose and attach a heat sink in this invention. So, it is possible to reduce the manufacturing cost, reduce the manufacturing time, simplify the manufacturing steps, avoid the problems of high thermal resistance and ageing caused by the heat sink, and thus enhance the heat dissipating efficiency and the product reliability.

### BRIEF DESCRIPTION OF THE DRAWINGS

The invention will become more fully understood from the detailed description given herein below illustration only, and thus is not limitative of the present invention, and wherein:

FIG. 1 is a schematic illustration showing a conventional LED light emitting apparatus; and

FIGS. 2 to 5 are schematic illustrations showing various light emitting apparatuses according to embodiments of the present invention.

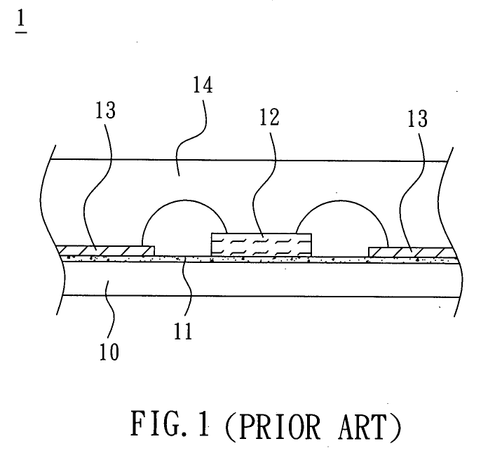

### DETAILED DESCRIPTION OF THE INVENTION

The present invention will be apparent from the following detailed description, which proceeds with reference to the accompanying drawings, wherein the same references relate to the same elements.

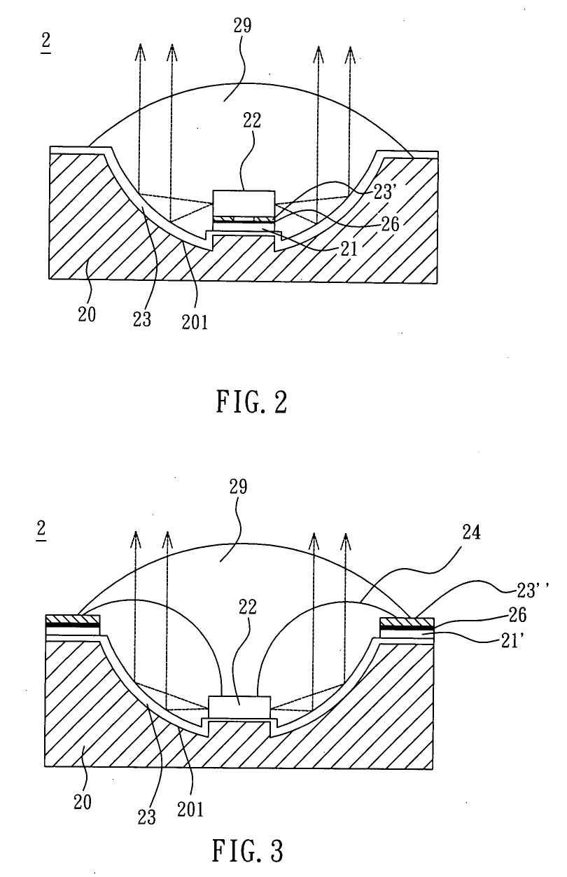

Referring to FIG. 2, a light emitting apparatus 2 according to a first embodiment of the invention includes a substrate 20, a first metal layer 23, a first insulating layer 21, a connecting layer 26, a second metal layer 23′, at least one light emitting device 22 and a protective layer 29.

In this embodiment, the material of the substrate 20 is mainly composed of the material with good thermal conductivity for providing proper heat dissipating efficiency. Preferably, the material of the substrate 20 is copper, copper alloy, or a thermal conductive material.

The first metal layer 23 of the light emitting apparatus 2 is disposed on the substrate 20. The material of the first metal layer 23 includes aluminum, magnesium, titanium or their alloys. Considering of the material characteristics of the first metal layer 23, the first insulating layer 21 may be directly formed by oxidizing, nitridizing or carbidizing the surface of the first metal layer 23. The material of the first insulating layer 21 accordingly may be aluminum oxide, magnesium oxide, titanium oxide, aluminum nitride, magnesium nitride, titanium nitride, aluminum carbide, magnesium carbide or titanium carbide. Also, the first metal layer 23 has a structure 201 for increasing the light emitting efficiency.

The light emitting device 22 is disposed at a predetermined position of the first metal layer 23 and on the substrate 20. In this embodiment, the light emitting device 22 includes a first electrode, a second electrode and a light emitting layer (not shown). More specifically, the light emitting device 22 may be a light emitting diode (LED), a laser diode (LD) or an organic light emitter diode (OLED).

The light emitting apparatus 2 of this embodiment may further include a second metal layer 23′ disposed on the first insulating layer 21. The second metal layer 23′ is directly electrically connected to the light emitting device 22, preferably, by wire bonding. The material of the second metal layer 23′ may be silver, gold, copper, aluminum or alloys thereof.

In order to dispose the second metal layer 23′ on the first insulating layer 21, the connecting layer 26 may further be formed between the second metal layer 23′ and the first insulating layer 21. The connecting layer 26 is adhesive, or has a property of enabling the second metal layer 23′ to be formed thereon. For example, the initial layer required may be made of chromium, titanium, nickel or alloys thereof when the second metal layer 23′ is formed by way of plating.

In this embodiment, the protective layer 29 is disposed on the light emitting device 22 to cover and protect the light emitting device 22. Meanwhile, the surface shape of the protective layer 29 are curved so that the protective layer 29 functions as a lens for diverging or converging the light outputted from the light emitting device 22 to meet various display requirements.

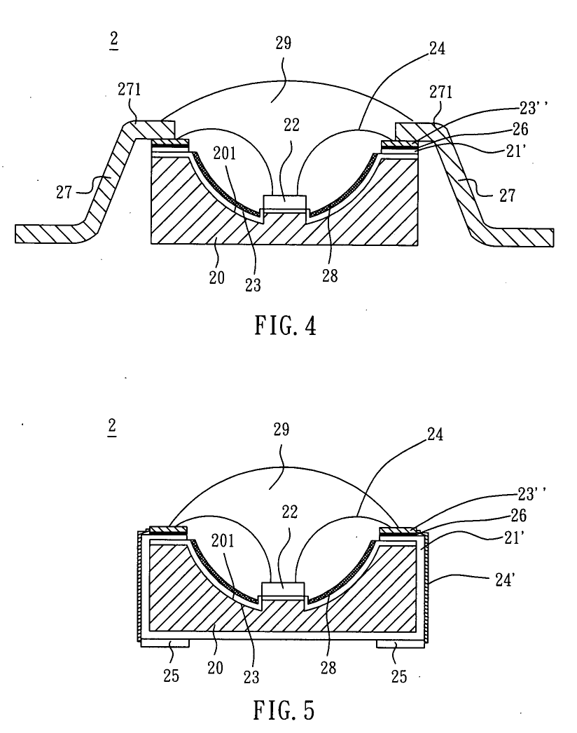

In this embodiment, the structure 201, for increasing the light emitting efficiency on the surface of the first metal layer 23, is a recess of spherical shape, elliptical shape or parabolic shape. Preferably, the light emitting device 22 is disposed at a focus of the recess. Thus, when the lateral light outputted from the light emitting device 22 strikes the structure 201, the curved structure 201 can reflect and converge the lateral light generated by the light emitting device 22 and then output the converged lateral light. Thus, the light emitting efficiency may be directly enhanced. In addition, the light emitting apparatus 2 may further include a reflective layer 28 disposed on the structure 201, as shown in FIG. 4, for enhancing the effects of reflection and convergence for the lateral light of the light emitting device 22. The material of the reflective layer 28 may include silver, gold or nickel.

In addition, the invention provides the second embodiment, shown in FIG. 3, in which the light emitting apparatus 2 further includes a second insulating layer 21′. The material of the second insulating layer 21′ may be aluminum oxide, magnesium oxide, titanium oxide, aluminum nitride, magnesium nitride, titanium nitride, aluminum carbide, magnesium carbide, titanium carbide, or their combinations, and may be deposited by oxidizing, nitridizing or carbidizing the surface of the first metal layer 23.

A third metal layer 23″ may be additionally disposed on the second insulating layer 21′ and electrically connected to the light emitting device 22 via a wire 24. In order to enable the third metal layer 23″ to be disposed on the second insulating layer 21′, a connecting layer 26 may also be formed between the third metal layer 23″ and the second insulating layer 21′. The connecting layer 26 is adhesive or has a property of enabling the third metal layer 23″ to be formed thereon. For example, the initial layer required may be made of chromium, titanium, nickel or alloys thereof when the third metal layer 23″ is formed by way of plating.

In this embodiment, the light emitting device 22 is electrically connected to the third metal layer 23″ via the wires 24 so that the light emitting device 22 may be directly disposed at the predetermined position of the first metal layer 23 so that it become unnecessary to dispose the insulating layer at the predetermined position. Of course, this is only an example and is not for limitations of the present invention.

The invention also provides another light emitting apparatus 2 according to the third embodiment, as shown in FIG. 4. The light emitting device 22 is electrically connected to an external circuit via a lead frame 27 disposed on the second insulating layer 21′. The lead frame 27 has a first electrode pin 271 and a second electrode pin 272, which may be respectively connected to the first electrode (not shown) and the second electrode (not shown) of the light emitting device 22 via the wires 24.

As shown in FIG. 5, the second insulating layer 21′ according to the fourth embodiment of the invention may also cover the external surface of the substrate 20. There is a plurality of connecting pads 25 disposed under the substrate 20 for being electrically connected with the light emitting device 22. The third metal layer 23″ above the second insulating layer 21′ is electrically connected to the first electrode and the second electrode of the light emitting device 22. The connecting pads 25 may be electrically connected to the second metal layers 23′ via wires (not shown) or the conductive layers 24′, respectively. To be noted, the above-mentioned connection way by wire is for illustrations only and is not for limitations of the present invention. For example, a U-shaped metal element (not shown) may be used to clip one side of the light emitting apparatus 2 so as to construct the second metal layer and connecting pads with the same functions of the previously mentioned elements. Thus, the connecting pads 25 underneath the second insulating layer 21′ may be electrically connected to the external circuit by way of surface mount technology (SMT).

In summary, the first metal layer of the light emitting apparatus is formed with the structure for increasing the light emitting efficiency, and the light emitting device is disposed at the predetermined position of the first metal layer in the light emitting apparatus according to the present invention. Regarding to the material characteristics of the first metal layer, an insulating layer can be directly formed after performing a ceramization procedure, and the light emitting device can be disposed on the insulating layer. Also, the light emitting efficiency is enhanced because the structure on the first metal layer can reflect and concentrate the light outputted from the light emitting device. Meanwhile, superior heat dissipating effect and thus longer lifetime of the light emitting apparatus may be achieved by using the substrate which has advantages of good thermal conductivity, large area, and may be composed of metal or alloys to guide and dissipate the heat generated by the light emitting device during operation. Compared with the prior art, it is unnecessary to dispose and attach a heat sink in this invention. So, it is possible to reduce the manufacturing cost, reduce the manufacturing time, simplify the manufacturing steps, avoid the problems of high thermal resistance and ageing caused by the heat sink, and thus enhance the heat dissipating efficiency and the product reliability.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light emitting apparatus, comprising:
a substrate;
a first metal layer disposed on the substrate and having a surface formed with a structure for increasing light emitting efficiency;
at least one light emitting device disposed at a predetermined position of the first metal layer; and
a protective layer for covering the light emitting device.

2. The light emitting apparatus according to claim 1, wherein the substrate comprises copper, copper alloy, and a thermal conductive material, and the first metal layer comprises aluminum, magnesium, titanium or alloys thereof.

3. The light emitting apparatus according to claim 1, further comprising a first insulating layer disposed between the first metal layer and the light emitting device, wherein the first insulating layer comprises aluminum oxide, magnesium oxide, titanium oxide, aluminum nitride, magnesium nitride, titanium nitride, aluminum carbide, magnesium carbide or titanium carbide.

4. The light emitting apparatus according to claim 3, further comprising a second metal layer disposed on the first insulating layer, wherein the second metal layer comprises silver, gold, copper, aluminum or alloys thereof.

5. The light emitting apparatus according to claim 4, wherein the light emitting device is electrically connected to the second metal layer by wire bonding, or the light emitting device is directly electrically connected to the second metal layer.

6. The light emitting apparatus according to claim 4, further comprising a first connecting layer disposed between the second metal layer and the first insulating layer so that the second metal layer is disposed on the first insulating layer, wherein the first connecting layer comprises chromium, titanium, nickel or alloys thereof.

7. The light emitting apparatus according to claim 6, wherein the first connecting layer is adhesive.

8. The light emitting apparatus according to claims 1, further comprising a second insulating layer disposed on a part of the first metal layer which does not belong to the structure for increasing light emitting efficiency, wherein the second insulating layer comprises aluminum oxide, magnesium oxide, titanium oxide, aluminum nitride, magnesium nitride, titanium nitride, aluminum carbide, magnesium carbide or titanium carbide.

9. The light emitting apparatus according to claim 8, further comprising a third metal layer disposed on the second insulating layer, wherein the light emitting device is electrically connected to the third metal layer via at least one wire.

10. The light emitting apparatus according to claim 9, further comprising a second connecting layer disposed between the third metal layer and the second insulating layer so that the third metal layer is disposed on the second insulating layer, wherein the second connecting layer comprises chromium, titanium, nickel or alloys thereof.

11. The light emitting apparatus according to claim 9, further comprising at least one connecting pad being electrically connected to the third metal layer via at least one wire.

12. The light emitting apparatus according to claim 8, wherein the second insulating layer is formed by oxidizing, nitridizing or carbidizing the surface of the first metal layer.

13. The light emitting apparatus according to claim 8, further comprising a lead frame comprising a first electrode pin and a second electrode pin, both of which are disposed on the second insulating layer and are electrically connected to the light emitting device.

14. The light emitting apparatus according to claim 8, wherein the second insulating layer covers an external surface of the substrate, and a plurality of connecting pads are disposed under the substrate for being electrically connecting with the light emitting device.

15. The light emitting apparatus according to claim 14, wherein the light emitting device and the connecting pad are electrically connected via a U-shaped metal element.

16. The light emitting apparatus according to claim 1, wherein the structure for increasing the light emitting efficiency is a recess, and the recess has a spherical shape, an elliptical shape, or a parabolic shape.

17. The light emitting apparatus according to claim 16, wherein the recess has a focus, and when the light emitting device is disposed at the predetermined position, the light emitting device is disposed at the focus of the recess.

18. The light emitting apparatus according to claim 1, further comprising a reflective layer disposed on the structure of the first metal layer, wherein the reflective layer comprises silver, gold or nickel.

19. The light emitting apparatus according to claim 1, wherein the light emitting device is a light emitting diode (LED), a laser diode (LD) or an organic light emitter diode (OLED), and the light emitting device comprises a first electrode, a second electrode, and a light emitting layer.

20. The light emitting apparatus according to claim 1, wherein the protective layer functions as a lens for diverging or converging the light outputted from the light emitting device.
